(19) United States
(12) Patent Application Publication
(10) Pub. No.: US 2016/0186325 A1
(43) Pub. Date: Jun. 30, 2016

(54) RESIN ARTICLE HAVING PLATING LAYER AND MANUFACTURING METHOD THEREOF, AND CONDUCTIVE FILM

(71) Applicant: CANON COMPONENTS, INC., Saitama-ken (JP)

(72) Inventor: Taisuke IWASHITA, Saitama-ken (JP)

(21) Appl. No.: 14/969,228

(22) Filed: Dec. 15, 2015

(30) Foreign Application Priority Data
Dec. 24, 2014 (JP) 2014-261208
Oct. 5, 2015 (JP) 2015-197947

(51) Int. Cl. C23C 18/18; H05K 1/03

(52) U.S. Cl. CPC C23C 18/1868; H05K 1/032

(57) ABSTRACT

There is provided with a method for manufacturing a resin article having a plating layer. A surface of a planar resin article is modified. The resin article is formed in a three-dimensional shape. The surface of the resin article that was formed in the three-dimensional shape is remodified. An electroless plating is performed on the resin article that was remodified to allow a plating layer to be deposited on the surface of the resin article at a portion that was modified.

### BACKGROUND OF THE INVENTION

1. Field of the Invention

The present invention relates to a resin article having a plating layer and a method for manufacturing the resin article, and a conductive film.

2. Description of the Related Art

In recent years, as electronic goods have been made smaller and lighter and made to have a variety of functions, the space for packaging components has become smaller. Therefore, for example when manufacturing a wiring board or the like, there are demands to pattern wiring on a substrate having a three-dimensional shape, and not merely pattern wiring on a substrate having a planar shape, in order to save space.

As a method for forming a wiring pattern on a substrate having a three-dimensional shape, a method employing a photolithography step and an etching step is disclosed in Japanese Patent Laid-Open No. 2013-125820. In Japanese Patent Laid-Open No. 2013-125820, a method using a three-dimensional photomask, a method for directly scanning a three-dimensional plastic body with light, and the like are used in photolithography. Also, in Japanese Patent Laid-Open No. 2012-149347, as a method for selectively plating a plastic surface, a method is disclosed that uses a step of performing ablation treatment on a surface of a plastic substrate using a laser, with the plastic substrate containing tectoaluminosilicate as an additive (catalyst).

### SUMMARY OF THE INVENTION

According to an embodiment of the present invention, a method for manufacturing a resin article having a plating layer comprises: modifying a surface of a planar resin article; forming the resin article in a three-dimensional shape; remodifying the surface of the resin article that was formed in the three-dimensional shape; and performing electroless plating on the resin article that was remodified to allow a plating layer to be deposited on the surface of the resin article at a portion that was modified.

According to another embodiment of the present invention, a resin article having a plating layer manufactured according to a method comprises: modifying a surface of a planar resin article; forming the resin article in a three-dimensional shape; remodifying the surface of the resin article that was formed in the three-dimensional shape; and performing electroless plating on the resin article that was remodified to allow a plating layer to be deposited on the surface of the resin article at a portion that was modified.

According to still another embodiment of the present invention, a resin article having a plating layer formed on the surface of the resin article comprises: a first surface and a second surface that point in different directions from each other, wherein the plating layer is formed continuously across the first surface and the second surface, and with a thickness of at least 0.01 μm and not more than 100 μm.

According to yet another embodiment of the present invention, a conductive film comprises: a resin article having a protrusion or recess formed in a surface; and a wiring pattern comprising a plating layer provided continuously between a surface of the protrusion or recess and a surface of the resin article adjacent to the protrusion or recess.

Further features of the present invention will become apparent from the following description of exemplary embodiments (with reference to the attached drawings).

### BRIEF DESCRIPTION OF THE DRAWINGS

FIG. 1 illustrates a method for manufacturing a resin article having a plating layer according to a first embodiment.

FIG. 2 is a flowchart of the method for manufacturing a resin article having a plating layer according to the first embodiment.

FIG. 3 shows a mask used in Example 1.

FIG. 4 illustrates a method for manufacturing a resin article having a plating layer according to an example and comparison examples.

FIG. 5 illustrates forming step in Example 1.

FIGS. 6A to 6D illustrate a method for manufacturing a resin article having a plating layer according to Example 4.

FIG. 7 shows an example of unevenness formed in a second embodiment.

FIGS. 8A to 8C illustrate the shape and filler of a resin article in a modified example.

### DESCRIPTION OF THE EMBODIMENTS

When forming a wiring pattern on a substrate having a three-dimensional shape using the methods disclosed in Japanese Patent Laid-Open No. 2013-125820 and Japanese Patent Laid-Open No. 2012-149347, it is necessary to selectively expose a substrate surface having a three-dimensional shape, not a planar shape. Therefore, a special apparatus is necessary, and mass production is not easy. In particular, the method disclosed in Japanese Patent Laid-Open No. 2012-149347 requires an expensive three-dimensional laser irradiation apparatus. Also, the method disclosed in Japanese Patent Laid-Open No. 2013-125820, in order to form a wiring pattern, requires a metal film forming step, a photoresist coating step, an exposing step, an etching step, and a photoresist separating step. Thus, there is the problem that labor and costs increase because many steps are required.

A method is also conceivable in which, after forming a metal layer in a pattern on a planar plastic substrate, the substrate is deformed to a three-dimensional shape by applying pressure or heat. However, in order to deform the substrate to a three-dimensional shape without causing breakage, cracks, or the like in the metal layer of a deformed portion, it is necessary for the metal layer to be considerably thick. Accordingly, for example when forming metal wiring having a greater wire width than the film thickness, particularly when manufacturing a transparent conductive film in which a metal mesh wiring has been formed, this method has problems.

According to one embodiment of the present invention, it is possible to easily form a plating layer pattern on a resin article surface having a three-dimensional shape.

### Embodiments of the Invention

Following is a description of embodiments where the present invention is applicable, with reference to drawings. However, the present invention is not limited by the embodiments below.

### First Embodiment

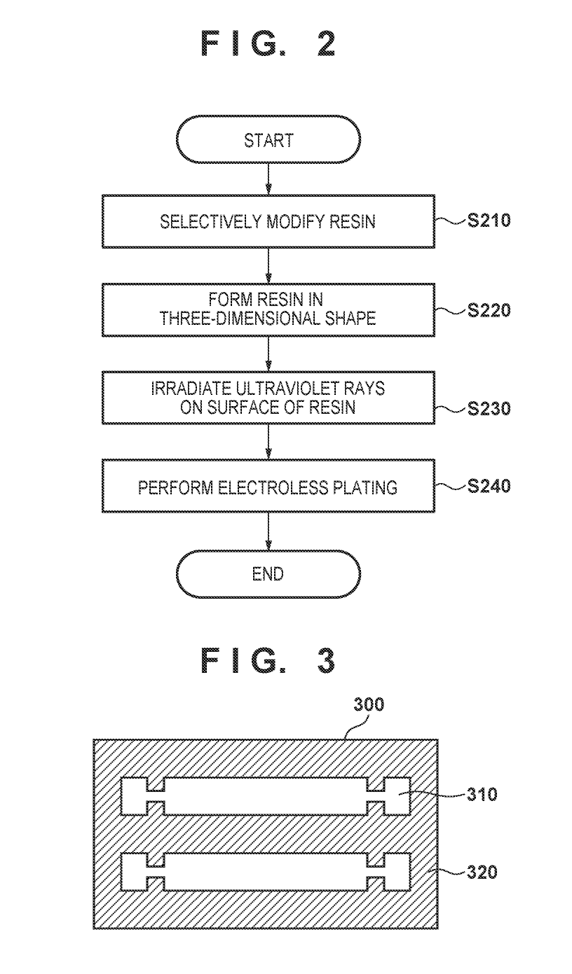

A method for manufacturing a resin article having a plating layer according to the present embodiment includes a modifying step, a forming step, an ultraviolet ray irradiation step, and a plating step. Below, these steps are described in detail with reference to the flowchart in FIG. 2.

(Modifying Step)

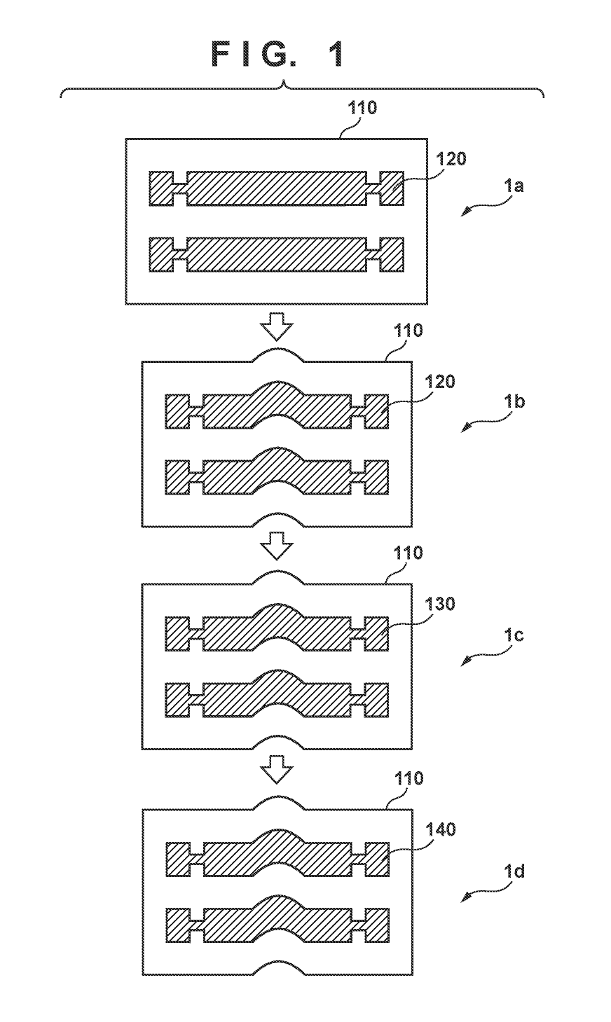

In the modifying step (S210), a portion of a surface of resin is selectively modified such that an electroless plating layer will be deposited. As shown in 1a of FIG. 1, in the modifying step, a portion 120 where the electroless plating layer is deposited on a resin article 110 is modified.

The type of resin of the resin article 110 is not particularly limited, but for example, may be a thermoplastic resin such as a polyolefin resin that includes a cyclic polyolefin resin such as a cyclo-olefin polymer resin, a polyimide resin, a vinyl resin of vinyl chloride or the like, a polyester resin, a polystyrene resin, a polycarbonate resin, a liquid crystal polymer resin, or the like. The resin article 110 may also be a mixture of two or more types of resin.

The resin article 110 is ordinarily for sale, and can easily be obtained. In one embodiment, the shape of the resin article 110 is selected such that modification by ultraviolet ray irradiation described later can easily be performed. For example, it is possible to use a resin article 110 that has a partially planar surface. Such a planar surface, for example, using an ultraviolet ray lamp, or by scanning irradiation of an ultraviolet ray laser having a linear irradiated region, can be modified in a single batch with low production costs. Also, such that a three-dimensional shape in the forming step described later can easily be performed, the resin article 110 may partially have a planar portion. In one specific embodiment, the resin article 110 has a planar face. In one embodiment, a commercially available film-like resin article 110 may be used. The thickness of the film-like resin article 110 is not particularly limited, but for example may be at least 10 μm and not more than 1.0 mm.

The film-like resin article 110 can be manufactured in the following manner, for example. Resin beads used as raw material are heated and melted, extruded with an extrusion die and formed as a film, then cooled, and thus a resin film is obtained.

Modification of the resin article 110 is performed by various methods that have already been used as electroless plating pre-treatment of the resin. Examples of the modification method include photoexcited ashing treatment, plasma ashing treatment, ultraviolet ray irradiation, acid treatment by chromic acid or the like, and alkali treatment or the like by sodium hydroxide or the like, but the modification method is not limited to these examples.

In the present embodiment, in the surface of the resin article 110, a portion where an electroless plating layer is to be deposited is selectively modified. With selective modification by ultraviolet ray irradiation, for example, by irradiating ultraviolet rays via a mask having a UV-transmissive portion that corresponds to a plating pattern to be deposited, it is possible to selectively irradiate ultraviolet rays on a desired modification portion 120. An example of the mask is shown in FIG. 3. A photomask 300 shown in FIG. 3 has a substrate 310 through which ultraviolet rays are transmitted, and a metal thin film 320 provided on the substrate 310 and through which ultraviolet rays are not transmitted. The metal thin film 320 is patterned such that an opening has a shape corresponding to the modification portion 120. An example of this sort of mask is a quartz chrome mask or the like. In FIG. 3, the portion corresponding to reference numeral 320 may be formed as a plate or a film of metal, ceramic, resin, or the like that does not transmit ultraviolet rays, and the portion corresponding to reference numeral 310 may be adopted as the opening portion. A metal mask or the like is one example of such a mask. Also, when performing modification by acid treatment, a desired portion 120 can be selectively modified by affixing on the resin article 110 a mask having an opening corresponding to the plating pattern to be deposited, then immersing in acid. In the present embodiment, a method of modifying by performing ultraviolet ray irradiation, whereby selective modification can easily be performed, is adopted.

Specifically, by irradiating ultraviolet rays in an atmosphere containing at least one of oxygen and ozone, the surface of the resin article 110 is modified. In one embodiment, ultraviolet rays having a wavelength of 243 nm or less are irradiated. In an atmosphere containing oxygen, oxygen molecules in the atmosphere are decomposed by ultraviolet rays having a wavelength of 243 nm or less, thus generating ozone. Further, active oxygen is generated in the course of ozone decomposing. The active oxygen generated in this way reacts with the surface of the resin article 110 that has likewise been activated by the ultraviolet rays, so the surface of the resin article 110 is oxidized, and thus a hydrophilic group such as a carboxyl group is formed on the surface of the resin article 110. Thus, it is conceivable that the surface of the resin article 110 is modified such that catalyst ions or a binder material that causes catalyst ions to bond with the resin article 110 are easily adsorbed.

Principles of the modification will be stated in further detail. Energy of photons of a specific wavelength is expressed by the following formulas.

E=Nhc/λ(KJ·mol⁻¹)

N=6.022×10²³mol⁻¹ (Avogadro's constant)

h=6.626×10⁻³⁷KJ·s (Plank's constant)

c=2.988×10⁸m·s⁻¹ (speed of light)

λ=light wavelength (nm)

Here, the bond energy of oxygen molecules is 490.4 KJ·mol⁻¹. From the photon energy formula, this bond energy is about 243 nm when converted to light wavelength. This indicates that oxygen molecules in the atmosphere will absorb ultraviolet rays with a wavelength of 243 nm or less and decompose. Thus, ozone O₃ is generated. Further, active oxygen is generated in the course of ozone decomposing. At this time, when there are ultraviolet rays with a wavelength of 310 nm or less, ozone is efficiently decomposed, and active oxygen is generated. Further, ultraviolet rays with a wavelength of 254 nm decompose ozone most efficiently.
O₂+hν (243 nm or less)→O(3P)+O(3P)
O₂+O (3P)→O₃(ozone)
O₃+hν (310 nm or less)→O₂+O (1D) (active oxygen)
   O(3P): ground state oxygen atom
   O(1D): excited oxygen atom (active oxygen)

Specifically, when ultraviolet rays having a wavelength of 243 nm or less are irradiated, oxygen in the atmosphere is decomposed, generating ozone. Further, active oxygen is generated in the course of ozone decomposing. Also, at the surface of the resin article 110, bonds in the molecules that constitute the resin article 110 are broken. At this time, molecules that constitute the resin article 110 react with active oxygen, and the surface of the resin article 110 oxidizes, that is, at the surface of the resin article 110 bonds such as C—O bonds, C=O bonds, and C(=O)−O bonds (carboxyl group skeletal structure portion) are formed. Such a hydrophilic group increases the chemical adsorption of the resin article 110 and a plating layer 130. Also, due to oxidation of the surface of the resin article 110, particularly after performing plating pre-treatment, a fine rough face is formed, so physical adsorption of the resin article 110 and the plating layer 130 increases due to an anchoring effect. Further, in a portion that has been modified, it is possible to selectively cause adsorption of catalyst ions or a binder that causes catalyst ions to bond with the resin article 110 when performing electroless plating.

Such ultraviolet rays can be irradiated using an ultraviolet ray lamp or an ultraviolet ray LED that continuously radiates ultraviolet rays. Examples of an ultraviolet ray lamp include a low pressure mercury lamp, an excimer lamp, and the like. A low pressure mercury lamp can irradiate ultraviolet rays having a wavelength of 185 nm and 254 nm. Also, for reference, an example of an excimer lamp that can be used in air is given below. Ordinarily an Xe₂ excimer lamp is used as an excimer lamp.
Xe₂ excimer lamp: wavelength 172 nm
KrBr excimer lamp: wavelength 206 nm
KrCl excimer lamp: wavelength 222 nm

When irradiating ultraviolet rays on the resin article 110, irradiation of ultraviolet rays is controlled such that the irradiation amount becomes a desired value. The irradiation amount can be controlled by changing the irradiation time. Also, the irradiation amount can be controlled by changing the output, lamp quantity, irradiation distance, or the like of the ultraviolet ray lamp.

In one embodiment, from the viewpoint of sufficiently depositing plating in a shorter time, the irradiation amount of ultraviolet rays in the modifying step is at least 400 mJ/cm² and not more than 810 mJ/cm² at a wavelength of 185 nm. For example, in an embodiment where the irradiation intensity of ultraviolet rays is 1.35 mW/cm² at a wavelength of 185 nm, the irradiation time of ultraviolet rays is at least 5 minutes from the viewpoint of performing sufficient modification. On the other hand, in one embodiment, from the viewpoint of improving production ability, the irradiation time of ultraviolet rays is not more than 15 minutes. Below, unless specifically stated otherwise, the irradiation amount and irradiation intensity of ultraviolet rays refer to values at a wavelength of 185 nm.

However, the plating deposit conditions may change depending on the type of plating solution, the type of resin, conditions in a reactivation step, degree of contamination of the resin surface, concentration, temperature, pH, and age-related degradation of the plating solution and fluctuation in output of the ultraviolet ray lamp, for example. Accordingly, the irradiation amount from the ultraviolet ray lamp can be set such that plating is selectively deposited only in a portion where ultraviolet rays have been irradiated.

Also, an ultraviolet ray laser can be used as an ultraviolet ray source. As necessary, an ultraviolet ray lamp or an ultraviolet ray LED may be used together with an ultraviolet ray laser. For example, after irradiating the portion 120 where the electroless plating layer is to be deposited with an ultraviolet ray laser, an ultraviolet ray lamp or an ultraviolet ray LED may be irradiated on the entire resin article 110. In this case, the irradiation amount of the ultraviolet ray laser, the ultraviolet ray lamp, and the ultraviolet ray LED is controlled such that the desired portion 120 is modified to the extent that an electroless plating layer will be deposited, and other portions are only modified to the extent that an electroless plating layer will not be deposited.

(Forming Step)

In the forming step (S220), the resin article 110 that was modified in the modifying step is formed in a three-dimensional shape. For example, in one embodiment, after applying heat to change the shape of the resin article 110, the resin article 110 is cooled to form a three-dimensional shape. For example, it is possible to deform the resin article 110 by applying heat to soften the resin article 110, then applying pressure in this state. By afterward cooling the resin article 110, it is possible to form the resin article 110 in a three-dimensional shape. In another embodiment, the resin article 110 is deformed by applying pressure to the resin article 110, but not applying heat to soften the resin article 110, to form the resin article 110 in a three-dimensional shape. The specific forming method is not particularly limited, but in one embodiment, forming is performed by hot-pressing or pressing the resin article 110. An example of the resin article 110 that has been formed in a three-dimensional shape is shown in 1b of FIG. 1.

The temperature for applying heat can be appropriately selected according to the type of the resin article 110 such that the resin article 110 can be deformed to be formed in a three-dimensional shape. For example, by applying heat to the resin article 110 at a temperature of at least 80° C. and not more than 200° C., it is possible to form the resin article 110 in a three-dimensional shape. In one embodiment, for ease of molding, the resin article 110 is heated to a higher temperature than a glass transition temperature Tg of the resin article 110.

The method of applying pressure in a case where heat is not applied is not particularly limited, and it is possible to appropriately select a method for applying force to the resin article 110 such that the resin article 110 can be deformed to be formed in a three-dimensional shape. For example, by applying force so as to bend the planar resin article 110, it is possible to deform the resin article 110 to be formed in a three-dimensional shape.

The hot pressing method is not particularly limited, and it is possible to perform pressing using a machine or the like while applying heat using a heater, a hot plate, a dryer, an oven, hot water, or the like. In one embodiment, a commercially available hot press machine may be used. The three-dimensional shape is not particularly limited, and an arbitrary shape can be adopted.

(Irradiation Step)

In the irradiation step (S230), the modifying step is additionally performed in a region that includes the desired modification portion 120 of the surface of the resin article 110 that has been formed in a three-dimensional shape. The modification method is not particularly limited, but in the present example, ultraviolet rays having a wavelength of no more than 243 nm, with which modifying can easily be performed, are irradiated. At this time, the irradiation amount is appropriately adjusted such that a plating layer will be formed only in the desired modification portion 120.

The inventors of the present application discovered that in a case where the resin article 110 was formed in a three-dimensional shape after modifying the resin article 110, in some cases a plating layer was not sufficiently deposited in the modification portion 120 even though plating was performed on the resin article 110. For example, when the resin article 110 was formed in a three-dimensional shape using a hot press, and when the resin article 110 was bent by applying pressure to the resin article 110, a plating layer was not deposited in part of the modification portion 120. Specifically, a tendency was seen for the plating layer to be difficult to deposit in a portion where heat was applied and a portion that was bent. As a result of investigation by the inventors, it was established that a plating layer can be deposited on the entire face of the modification portion 120 by additionally irradiating ultraviolet rays to again modify the resin article 110 after forming the resin article 110 in a three-dimensional shape. In one embodiment, remodifying was performed on at least a portion of the resin article 110 that was heated and a portion that was bent. However, in the irradiation step, it is not necessary to remodify the resin article 110 using ultraviolet ray irradiation. For example, remodifying of the resin article 110 can be performed by photoexcited ashing treatment, plasma ashing treatment, acid treatment by chromic acid or the like, or alkali treatment using sodium hydroxide or the like.

The inventors presumed the following regarding such a phenomenon. That is, it is conceivable that the modification portion 120 of the resin article 110 was deactivated by treatment to form the resin article 110 in a three-dimensional shape. It is conceivable that one reason for this is that when the modification portion was heated, the adsorption group decreases by a dehydration reaction of the adsorption group, and the modification portion oxidizes and disappears by heating to a temperature of at least the glass transition temperature. For example, the dehydration reaction can be expressed as: —COOH+—OH→—COO—(ester bond)+H₂O↑. Also, it is conceivable that when pressure was added to the modification portion, the modification portion embeds within the resin article 110. Further, it is conceivable that in a case where the modification portion was bent, as a result of the resin being extended in the bent portion, the layer of the modified resin becomes thinner, so it becomes difficult for the plating layer to be deposited. Also, it is conceivable that in a case where the modification portion was bent, some degree of surface oxidization is necessary in order to adsorb the catalyst ions or binder material, but the oxidization density drops, so it becomes difficult for the plating layer to be deposited.

In the irradiation step, it is possible to perform irradiation on the entire surface of the resin article 110 that was formed in a three-dimensional shape. In one embodiment, irradiation can be performed on both the modification portion 120 and on portions adjacent to the modification portion 120. Also, irradiation may be performed on only a portion of a region that includes the desired modification portion 120 on the surface of the resin article 110. By setting an irradiation amount such that a deactivated modification portion is reactivated, it is possible to prevent depositing of a plating layer in a portion other than the modification portion 120. Thus, in the irradiation step it is not necessary to restrict the irradiated region by masking or the like. By not requiring masking treatment or the like in the irradiation step, production ability can be improved.

An example of the ultraviolet ray lamp (apparatus), the ultraviolet ray irradiation amount, and the ultraviolet ray source are similar to those in the modifying step, so a detailed description of those is omitted here. The ultraviolet ray irradiation time is set such that a deactivated portion is reactivated, such that a desired pattern will be deposited. If the irradiation time is insufficient for achieving reactivation, depositing of plating of the desired pattern will be insufficient, but in a case where the irradiation time is too long, depositing occurs in portions other than the desired pattern. The irradiation time setting may be changed according to resin material properties, ultraviolet ray irradiation conditions, plating conditions, temperature, and the like. For example, in an embodiment where the irradiation intensity of ultraviolet rays is 1.35 mW/cm² at a wavelength of 185 nm, the irradiation time of ultraviolet rays is at least 1 minute and less than 2 minutes 30 seconds. When the irradiation time of ultraviolet rays is less than 1 minute, there is a possibility that reactivation will not be sufficient, and so depositing of a plating layer in the desired pattern will be insufficient. Also, when the irradiation time of ultraviolet rays is at least 2 minutes 30 seconds, there is a possibility that a plating layer will be deposited in a portion other than the desired pattern.

### (Electroless Plating Step)

In the electroless plating step (S240), electroless plating is performed on the resin article 110 that has been irradiated with ultraviolet rays in the irradiation step. By electroless plating, it is possible to provide a plating layer on the modification portion 120 of the resin article 110. In the electroless plating step, it is possible to use a similar method as is already being used in electroless plating on resin. For example, the electroless plating step can be performed using an electroless plating solution set, such as a Cu—Ni plating solution set “AISL” made by JCU Co.

In the electroless plating step, as shown in 1c of FIG. 1, the plating layer 130 is selectively deposited on the modification portion 120 of the resin article 110 by performing electroless plating on the resin article 110. In one embodiment, the plating layer is continuously and thinly formed on the modification portion 120 of the resin article 110, which has a three-dimensional shape. Here, ‘continuously’ means a state in which the plating layer has no cracks, breaks, or disconnections. In order to obtain a continuous plating layer 130, the thickness of the plating layer 130 is at least 0.01 μm in one embodiment, and at least 0.1 μm in still another embodiment. Also, according to the method of the present embodiment a thin plating layer 130 is easily obtained, with the thickness of the plating layer 130 being no more than 5.0 μm in one embodiment, and 0.4 μm in another embodiment. In one embodiment in which the resin article 110 is modified by ultraviolet rays, nano-level roughness occurs in the modification portion 120, so high adhesiveness due to an anchoring effect between the deposited plating layer 130 and the resin article 110 is obtained.

The specific electroless plating method is not particularly limited. Examples of electroless plating that can be adopted include electroless plating employing a formalin electroless plating bath, electroless plating in which hypophosphorous acid, which has a slow deposit speed but is easily managed, is used as a reducing agent, and so forth. The type of plating layer to be deposited is not limited to metal, as long as depositing by a catalyst is possible. In one embodiment, a ceramic film that is a metal oxide is formed. Also, in order to form a thicker plating film, the plating layer 130 may be formed using a high-speed electroless plating method. As more specific examples of electroless plating, there are electroless nickel plating, electroless copper plating, electroless copper-nickel plating, zinc oxide plating, and the like.

In one embodiment, the electroless plating can be performed by the below method.

1. The resin article is immersed in an alkali solution and oil is removed to improve hydrophilicity.

2. The resin article is immersed in a solution containing a binder of the resin article and catalyst ions, such as a cation polymer.

3. The resin article is immersed in a solution containing catalyst ions.

4. The resin article is immersed in a solution containing a reducing agent, causing reduction and depositing of catalyst ions.

5. Plating is deposited on the deposited catalyst.

As shown in 1d of FIG. 1, in order to increase film thickness of the plating layer 130, electrolytic plating may further be performed on the resin article 110. The specific method of electrolytic plating is not particularly limited, and for example, nickel plating, copper plating, copper-nickel plating, or the like can be performed. Further, examples of material for electrolytic plating include zinc, silver, cadmium, iron, cobalt, chromium, nickel-chromium alloy, tin, tin-lead alloy, tin-silver alloy, tin-bismuth alloy, tin-copper alloy, gold, platinum, rhodium, palladium, palladium-nickel alloy, zinc oxide, and the like. Also, addition of a substitution plating treatment of silver or the like as necessary is also allowable. According to the method of the present embodiment, the thickness of the plating layer 140 is no more than 100 μm in one embodiment.

By the above steps, the resin article 110 having a plating layer is obtained. The resin article 110 having a plating layer, obtained by plating the resin article 110 according to a desired wiring pattern, can be used as a wiring board.

Also, the resin article 110 having a plating layer can be used as a conductive film for a display. In recent years, in an apparatus having a display such as a television or a smartphone, there are demands for a reduction in size of the apparatus itself, and demands for increased screen size to improve visibility. In a display, often a conductive film is used in which a central region corresponds to a display region, and has wiring provided in a circumferential region. There is vigorous competition to reduce the size of the circumferential region (so-called frame region) of the display where wiring is provided, in order to satisfy the conflicting demands of increasing the size of the display region without increasing the size of the apparatus. However, an approach of reducing wiring pitch in order to reduce the size of the frame region ordinarily requires an expensive process of laser processing or the like. On the other hand, according to the present embodiment, it is easy to manufacture a conductive film in which, in a conductive state of the center region wiring and the circumferential region wiring, the conductive film is bent between the center portion and the circumferential region. By bending the circumferential region to the inside, it is possible to make the frame region as small as possible.

### Second Embodiment

Ordinarily, a touch panel has a structure in which a transparent conductive film for sensing touch is layered on a display having a liquid crystal screen or the like. As the transparent conductive film, for example, it is possible to use a resin film in which a mesh-like wiring pattern for sensing touch has been formed.

An ordinary touch panel surface is planar or is a smooth curved surface. Therefore, it is difficult to perform so-called touch typing. For example, it is not easy for a visually impaired person to operate a touch panel. Also, in circumstances in which it is difficult to pay attention to a touch panel, for example while driving, it is not easy to operate the touch panel. Japanese Patent Laid-Open No. 2015-5279 describes solving such a problem by providing a cover on a touch panel, but on the other hand, problems occur in that display screen visibility is impaired, and a sensor function does not operate for the cover portion.

In order to solve such problems, it is desired that operation be made easy by providing unevenness on the touch panel. For example, it is conceivable that operation of the touch panel without viewing the touch panel will become easy by providing unevenness in a keyboard shape or unevenness in a switch shape. For example, Japanese Patent Laid-Open No. 2014-127017 describes providing unevenness in a touch sensor sheet. Specifically, Japanese Patent Laid-Open No. 2014-127017, in consideration of a problem that an ITO transparent electrode often used in a touch panel has low flexibility and therefore is easily disconnected when providing unevenness, describes using a silver paste or the like having elasticity as electrode material in an uneven portion.

However, there is the problem that an electrode configured with silver paste has high resistance, and this problem particularly notable when manufacturing a particularly large touch panel. Also, it is not easy to provide a fine electrode pattern with a method using silver paste, and in addition, such a method has the problem of high production cost because production steps are complicated.

In the second embodiment, the method of the first embodiment is applied to manufacture a conductive film for a display having unevenness on its surface. In the manufacturing method according to the present embodiment, a film-like resin article, which can be used as base material of a conductive film for a display, is used as the resin article 110. Also, in Step S210, modification is performed such that an electroless plating layer is deposited according to a wiring pattern for conductive film. Further, in Step S220, the resin article 110 is molded in a three-dimensional shape such that unevenness is provided on the surface of the resin article 110. Steps thereafter can be performed in the same manner as in the first embodiment.

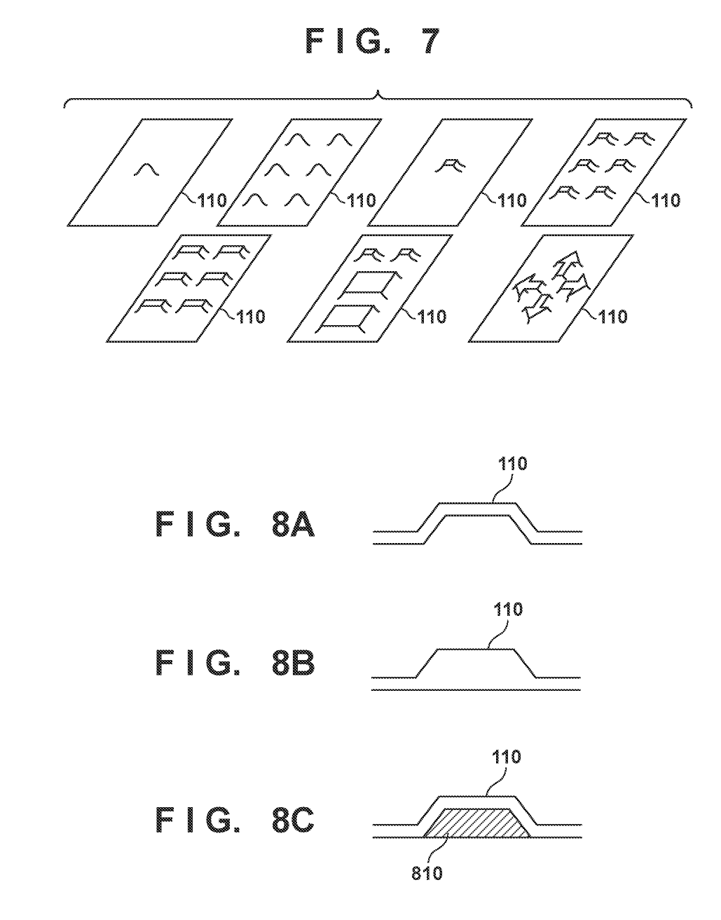

In Step S220, for example, it is possible to provide unevenness on the surface of the resin article 110 by hot pressing the resin article 110 using a mold having a desired uneven shape. The provided unevenness may be a portion protruding or recessed from a planar face or curved face that prescribes the surface of the resin article 110, for example. Examples of uneven shapes that can be provided in Step S220 are shown in FIG. 7. The height of a protrusion or the depth of a recess from the adjacent surface of the resin article 110 is not particularly limited, but may be for example at least 0.1 mm and not more than 1 cm.

According to the present embodiment, a conductive film is obtained that has a wiring pattern configured with the plating layer 130 provided continuously between the surface of a protrusion or a recess and the surface of the resin article 110 adjacent to the protrusion or recess. In Step S230, the modification portion 120, particularly a region between the protrusion or recess and the portion adjacent to the protrusion or recess, is reactivated, so it is possible to form a continuous wiring pattern in Step S240.

According to the method of the present embodiment, the wiring pattern of the conductive film is formed by plating after providing an uneven shape in the conductive film. Therefore, it is possible to provide a continuous wiring pattern in the conductive film even at a location of unevenness. Also, the uneven shape to be formed is not particularly limited. Further, because the wiring pattern is configured with a continuous plating layer, the wiring pattern has low electrical resistance. Therefore, the conductive film obtained by the present embodiment is easily applied to a touch panel having a large screen. Also, because the position modified with ultraviolet rays has a high degree of selectability, it is easy to provide a fine wiring pattern. Therefore, according to the present embodiment, it is possible to easily manufacture a transparent conductive film having a high degree of light transmission and high visibility on the back side of the conductive film.

### MODIFIED EXAMPLES

FIGS. 8A to 8C show examples of the resin article 110 having unevenness formed in Step S210. As shown in FIG. 8A, unevenness can be formed, for example using a hot press, such that the film-like resin article 110 has uniform thickness. On the other hand, as shown in FIG. 8B, unevenness can also be formed, for example using a hot press, such that the film-like resin article 110 has differing thickness. As a specific example, unevenness can be formed in the resin article 110 such that the thickness of the resin article 110 is greater in a protrusion of the resin article 110 than in another portion. Also, unevenness can be formed in the resin article 110 such that the thickness of the resin article 110 is less in a recess of the resin article 110 than in another portion. According to this sort of an embodiment, when the obtained conductive film has been applied to the display, an effect is obtained that the transparent conductive film does not deform even when a protrusion or the like of the resin article 110 is pushed. In the embodiment shown in FIG. 8B, the wiring pattern may be formed in either face of the resin article 110, but in one embodiment, the wiring pattern is formed in a face that has unevenness. In any case, the modification portion 120 easily disappears when molding the resin article 110 in a three-dimensional shape using a hot press or the like, but the modification portion 120 is reactivated by the irradiation step in Step S230.

In still another embodiment, a filler 810 is filled into a recess of the resin article 110 as shown in FIG. 8C. According to this sort of configuration, even in a case where the film-like resin article 110 has a uniform thickness, when the obtained conductive film has been applied to the display, an effect is obtained that the transparent conductive film does not deform even when a protrusion or the like of the resin article 110 is pushed. A transparent filler can be used as the filler 810 in order to insure visibility. The transparent filler is not particularly limited, and transparent resin can be used, for example.

An example of the filler 810 is a solid that has been constituted from a plurality of fibrous crystals, and a specific example is ulexite (TV rock). Also, artificial TV rock in which quartz glass has been bundled can also be used. This sort of solid has a structure like those in which optical fiber has been bundled, and has a function of delivering light that entered from one direction to an opposite side. By using this sort of solid, an effect is obtained that an image on a display appears to the user as if floating on the solid surface.

Another example of the filler 810 is an actuator. An actuator is an apparatus capable of changing length, size, or the like according to a signal, and by inserting an actuator, it is possible to deform a protrusion of the resin article 110 where the filler 810 has been inserted. For example, when a protrusion has been formed in the shape of a rectangular button in the resin article 110, graphics such as characters or numerals can be made to float on the protrusion using the actuator.

Also, a graphic pattern of characters, numerals or the like can be provided by plating, in addition to a wiring pattern for sensing touch input, on the resin article 110. According to this sort of configuration, for example, it is possible to form a protrusion in the shape of a rectangular button on the resin article 110, and provide characters, numerals or the like that describe the button on this protrusion. In this case, it is possible to form a wiring pattern on one face of the resin article 110, and form a graphic pattern on the other face. Also, a configuration may be adopted in which a protrusion having the shape of a character, a numeral, or the like is directly formed on the resin article 110, and a wiring pattern is formed on that protrusion.

### Embodiment 3

The method of the first embodiment can also be used when performing plating on all faces of the resin article 110, and not only in a case where plating is performed on part of the resin article 110, for example on all of one face of the resin article 110. A special ultraviolet ray irradiation apparatus is necessary in order to irradiate ultraviolet rays on all faces of the resin article 110 having a three-dimensional shape. However, according to the method of the first embodiment, the resin article 110 is molded into a three-dimensional shape after the planar resin article 110 has been irradiated with ultraviolet rays. Therefore, it is not essential to use a special ultraviolet ray irradiation apparatus. In this sort of case as well, the modification portion 120 easily disappears when molding the resin article 110 in a three-dimensional shape using a hot press or the like, but the modification portion 120 is reactivated by the irradiation step in Step S230, so an effect of obtaining a uniform plating layer is expected.

Also, the method of the first embodiment can also be used when manufacturing a resin article having a plating layer in a three-dimensional shape where decorative plating has been performed. For example, by applying the method of the first embodiment, it is possible to manufacture a keyboard that has been plated on all faces, and it is possible to manufacture a keyboard having a plating layer in the shape of a graphic of a character, a numeral, or the like in a keytop portion.

Further, the wiring pattern may be formed on both faces of the resin article 110, not only one face. Thus, for example, it is possible to form an X electrode and a Y electrode of a touch panel in one resin article 110.

A resin article having a plating layer that was formed according to the embodiments described above can be used for a conductive film, a transparent conductive film, an electrode for a display, an electrode for a touch panel, an electrode for a solar battery, an electromagnetic wave shield, or an antenna, for example.

### Example 1

A sheet-like cyclo-olefin polymer (made by Japan Zeon Corp., ZeonorFilm ZF-16, thickness 100 μm) was used as a resin article. The glass transition temperature of this resin article was 160° C.

[Modifying Step]

First, the photomask 300 shown in FIG. 3 was placed on the resin article. A compound quartz substrate was used as the substrate 310, and a chrome thin film was used as the metal thin film 320. In FIG. 3, a hatched portion indicates a portion where ultraviolet rays were not transmitted.

Next, ultraviolet rays were irradiated via an ultraviolet ray mask. Details of the ultraviolet ray lamp (low pressure mercury lamp) used in this example are given below.

Low pressure mercury lamp: UV-300 made by Samco Corp. (primary wavelengths 185 nm, 254 nm)

Illuminance at irradiation distance 3.5 cm:
5.40 mW/cm² (254 nm)
1.35 mW/cm² (185 nm)

Specifically, on the resin article, using the above ultraviolet ray lamp, ultraviolet rays of 1.35 mW/cm² (185 nm) were irradiated for 10 minutes at a distance of 3.5 cm from the ultraviolet ray lamp. In this case, the total amount of exposure was 1.35 mW/cm² ×600 seconds=810 mJ/cm².

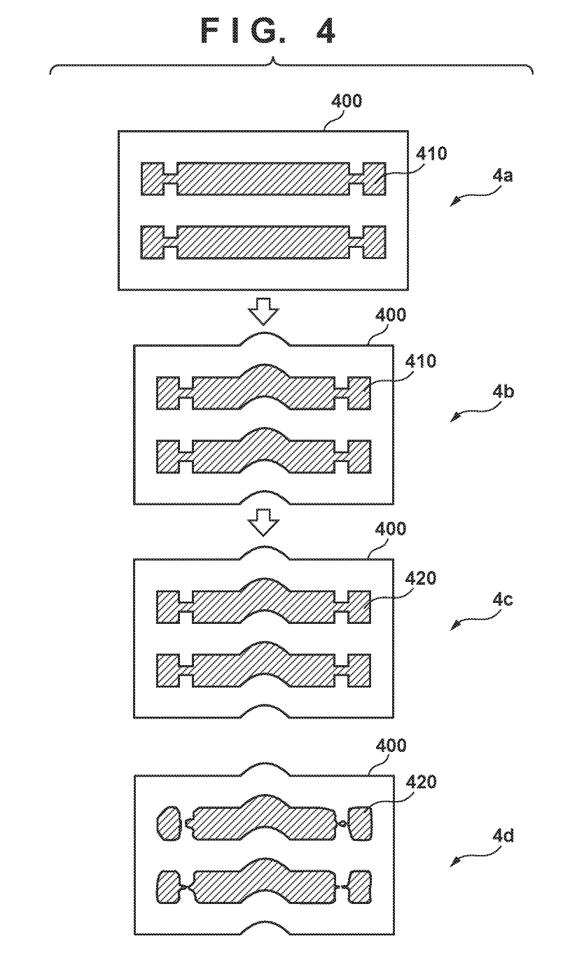

A resin article 400 after modification is shown in 4a of FIG. 4. The resin article 400 has a modification portion 410 where the ultraviolet rays were irradiated.

[Forming step]

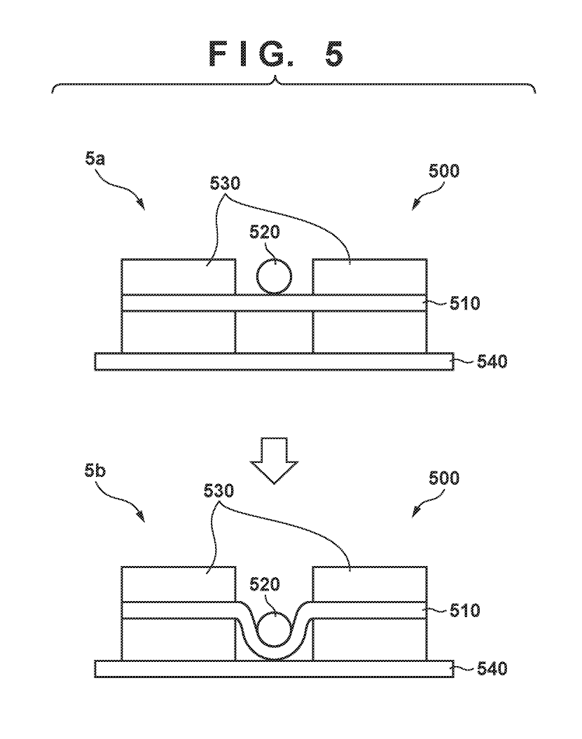

Next, the resin article was formed in a three-dimensional shape by hot pressing the resin article at a temperature of 190° C. Specifically, the three-dimensional shape was formed using an apparatus 500 shown in FIG. 5. As shown in 5a of FIG. 5, a resin article 510, in a state of being fixed by a fixing member 530, was heated by a heater 540 that was set to a temperature of 190° C. A digital hot plate DP-2S made by As One Corp. was used as the heater 540. In this state, pressure was applied to the resin article 510 for 5 minutes with a heated pressing member 520. A state in which pressure is being applied to the resin article 510 is shown in 5b of FIG. 5. In this way, the resin article 510 was formed in a three-dimensional shape. The obtained resin article 400 is shown in 4b of FIG. 4.

[Irradiation step]

Next, ultraviolet rays were irradiated for 1 minute 30 seconds on the resin article 400. The conditions of irradiation of ultraviolet rays were the same as in the modifying step.

[Plating Step]

Next, electroless plating was performed on the resin article 400 using a Cu—Ni plating solution set “AISL” made by JCU Co. Specific treatment conditions were as follows. After finishing each step, a first water rinse (subjecting the resin article 400 to three round trips in pure water at room temperature) and a second water rinse (agitating for 1 minute (5 minutes after conditioner step) in pure water at 50° C.) were performed.

TABLE 1

| | Treatment | |
|---|---|---|
| Step | Conditions | Remarks |
| Alkali treatment | 50° C., 2 min. | Oil removal, wettability |
| | | improved |
| Water rinse + dry (air | | |
| blow) | | |
| Conditioner step | 50° C., 2 min. | Binder of catalyst ions |
| | | and substrate provided |
| Warm water rinse + water | | |
| rinse + dry (air blow) | | |
| Activator | 50° C., 2 min. | Catalyst ions provided |
| Water rinse + dry (air | | |
| blow) | | |
| Accelerator | 40° C., 2 min. | Catalyst ions reduction, |
| | | conversion to metal |
| Water rinse + dry (air | | |
| blow) | | |
| Electroless Cu—Ni | 60° C., 5 min. | Electroless plating |
| plating | | deposited |
| Water rinse + dry (air | | |
| blow) | | |

When electroless plating according to the steps shown in Table 1 was finished, a plating layer had been formed on all faces of the modification portion 410 that was modified by ultraviolet ray irradiation in the modifying step. On the other hand, a plating layer had not been formed outside the modification portion 410. The resin article 400 having a plating layer 420 formed in the present example is shown in 4c of FIG. 4.

### Example 2

In Example 2, the irradiation time of ultraviolet rays on the resin article 400 in the irradiation step was set to 1 minute. Steps other than the irradiation step were performed in the same manner as in Example 1.

When electroless plating according to the steps shown in Table 1 was finished, there was a region where a plating layer had not been formed in part of the modification portion 410 that was modified by ultraviolet ray irradiation in the modifying step. However, there were no disconnections in a fine region of the modification portion 410. On the other hand, a plating layer had not been formed outside the modification portion 410.

### Example 3

In Example 3, the irradiation time of ultraviolet rays on the resin article 400 in the irradiation step was set to 2 minutes 30 seconds. Steps other than the irradiation step were performed in the same manner as in Example 1.

When electroless plating according to the steps shown in Table 1 was finished, a plating layer had been formed on all faces of the modification portion 410 that was modified by ultraviolet ray irradiation in the modifying step. On the other hand, partial formation of a plating layer was seen also outside the modification portion 410.

### Comparison Example 1

In Comparison Example 1, the irradiation step was not performed. The modifying step, the forming step, and the plating step were performed in a similar manner as Example 1.

When electroless plating according to the steps shown in Table 1 was finished, a region where a plating layer had not been formed existed in the modification portion 410 that was modified by ultraviolet ray irradiation in the modifying step. Also, a fine region of the modification portion 410 was disconnected. The resin article 400 having a plating layer 420 formed in the present example is shown in 4d of FIG. 4.

### Comparison Example 2

In Comparison Example 2, after the modifying step, the plating step was performed, and then the forming step was performed. On the other hand, the irradiation step was not performed. The modifying step, the forming step, and the plating step were performed in a similar manner as Example 1.

When the obtained resin article 400 was checked, blackening discoloration and cracks were seen in a portion of the plating layer 420 where pressure was applied during hot pressing.

### Example 4

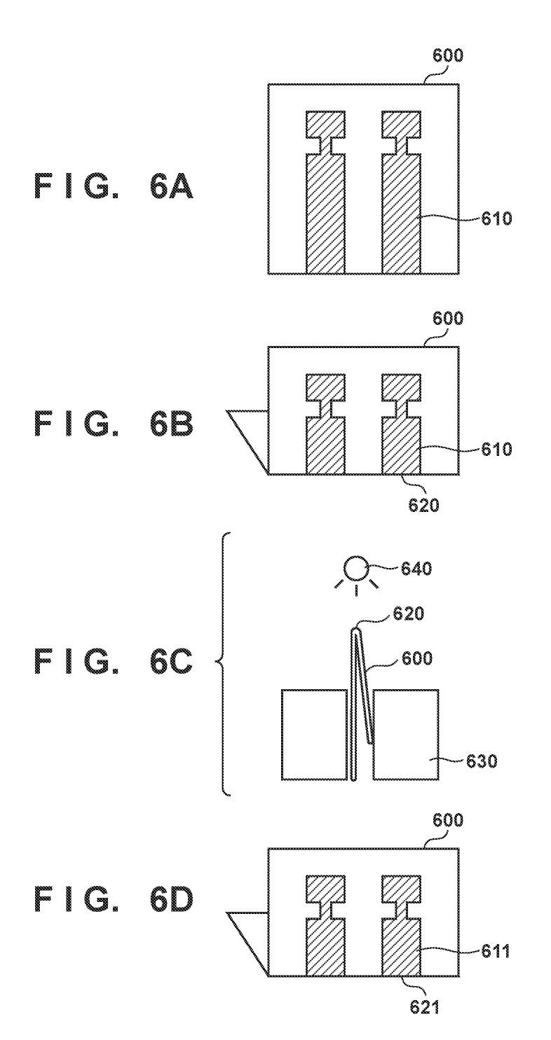

In Example 4, a sheet-like cyclo-olefin polymer (made by Japan Zeon Corp., ZeonorFilm ZF-14, thickness 100 μm) was used as a resin article. The modifying step was performed in the same manner as Example 1. A resin article 600 after modification is shown in FIG. 6A. The resin article 600 has a modification portion 610 where ultraviolet rays were irradiated.

In the forming step, the resin article is formed in a three-dimensional shape by applying force to bend the resin article without applying heat to the resin article. Specifically, as shown in FIG. 6B, the resin article 600 was formed in a three-dimensional shape. Next, as shown in FIG. 6C, in the irradiation step, irradiation of ultraviolet rays on the resin article 600 was performed in a state with the three-dimensional shape fixed by a fixing member 630. Specifically, ultraviolet rays were irradiated on a bending portion 620 of the resin article 600 using an ultraviolet ray lamp 640. The ultraviolet ray irradiation time was 2 minutes. The ultraviolet ray irradiation conditions were the same as in the modifying state, except that the irradiation distance was 3.5 cm from the bending portion 620. Then, the plating step was performed in the same manner as Example 1.

The resin article 600 after the plating step is shown in FIG. 6D. The resin article 600 had a plating layer 611 that was formed by electroless copper-nickel plating. When electroless plating was finished, a plating layer 611 had been formed on all faces of the modification portion 610 that was modified by ultraviolet ray irradiation in the modifying step. On the other hand, a plating layer had not been formed outside the modification portion 610. The plating layer 611 had been formed in the modification portion 610 also at a bending portion 621. In a test in which electrical current was applied to the plating layer 611 while sandwiching the bending portion 621 from both sides, it was confirmed that the plating layer 611 was conducting electricity from both sides of the bending portion 621, that is, it was confirmed that the plating layer 611 was continuous.

### Comparison Example 3

In Comparison Example 3, the irradiation step was not performed, and the modifying step, the forming step, and the plating step were performed in a similar manner as Example 4 to manufacture a resin article having a plating layer. In the resin article having a plating layer obtained in Comparison Example 3, a plating layer was not sufficiently formed in a bending portion. Also, it could not be confirmed that the plating layer was conducting electricity from both sides of the bending portion.

As described above, it was confirmed that by first performing the modifying step, then performing the forming step, then performing the irradiation step, and lastly performing the plating step, a plating layer will be sufficiently deposited in a portion that was modified in the modifying step.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2014-261208, filed Dec. 24, 2014, and 2015-197947, filed Oct. 5, 2015, which are hereby incorporated by reference herein in their entirety.

What is claimed is:

1. A method for manufacturing a resin article having a plating layer, the method comprising:
modifying a surface of a planar resin article;
forming the resin article in a three-dimensional shape;
remodifying the surface of the resin article that was formed in the three-dimensional shape; and
performing electroless plating on the resin article that was remodified to allow a plating layer to be deposited on the surface of the resin article at a portion that was modified.

2. The method for manufacturing a resin article having a plating layer according to claim 1, wherein in the modifying, part of the surface of the planar resin article is selectively modified.

3. The method for manufacturing a resin article having a plating layer according to claim 1, wherein in the modifying, ultraviolet rays having a wavelength of 243 nm or less are irradiated on part of the surface of the resin article.

4. The method for manufacturing a resin article having a plating layer according to claim 1, wherein in the modifying, an ultraviolet ray laser having a wavelength of 243 nm or less is irradiated on part of the surface of the resin article.

5. The method for manufacturing a resin article having a plating layer according to claim 3, wherein in the modifying, ultraviolet rays are irradiated in an atmosphere containing at least one of oxygen and ozone.

6. The method for manufacturing a resin article having a plating layer according to claim 1, wherein in the forming, the resin article is heated.

7. The method for manufacturing a resin article having a plating layer according to claim 1, wherein in the forming, pressure is applied to the resin article.

8. The method for manufacturing a resin article having a plating layer according to claim 1, wherein in the remodifying, ultraviolet rays are irradiated on both a portion that was modified in the modifying, and a portion adjacent to the portion that was modified in the modifying.

9. The method for manufacturing a resin article having a plating layer according to claim 8, wherein the wavelength of ultraviolet rays in the remodifying is 243 nm or less.

10. The method for manufacturing a resin article having a plating layer according to claim 1, wherein the surface of the resin article contains a cyclo-olefin polymer, a polystyrene resin, a polyimide resin, a polyolefin resin, a polyester resin, a polycarbonate resin, a liquid crystal polymer resin, or a vinyl resin.

11. A resin article having a plating layer manufactured according to the method comprising:
modifying a surface of a planar resin article;
forming the resin article in a three-dimensional shape;
remodifying the surface of the resin article that was formed in the three-dimensional shape; and
performing electroless plating on the resin article that was remodified to allow a plating layer to be deposited on the surface of the resin article at a portion that was modified.

12. A resin article having a plating layer formed on the surface of the resin article, comprising:
a first surface and a second surface that point in different directions from each other,
wherein the plating layer is formed continuously across the first surface and the second surface, and with a thickness of at least 0.01 μm and not more than 100 μm.

13. The resin article according to claim 12, wherein the plating layer is a metal film or a metal oxide film.

14. A conductive film, comprising:
a resin article having a protrusion or recess formed in a surface; and
a wiring pattern comprising a plating layer provided continuously between a surface of the protrusion or recess and a surface of the resin article adjacent to the protrusion or recess.
